(19) United States
(12) Patent Application Publication
(10) Pub. No.: US 2009/0315087 A1
(43) Pub. Date: Dec. 24, 2009

(54) IMAGE SENSOR AND METHOD FOR MANUFACTURING THE SAME

(76) Inventor: Ji-Hwan Park, Chungju-si (KR)

Correspondence Address: SHERR & VAUGHN, PLLC, 620 HERNDON PARKWAY, SUITE 320, HERNDON, VA, 20170, US

(21) Appl. No.: 12/486,876

(22) Filed: Jun. 18, 2009

(30) Foreign Application Priority Data
Jun. 20, 2008 (KR) 10-2008-0058124

(51) Int. Cl. H01L 31/112; H01L 31/18

(52) U.S. Cl. 257/292; 438/70; 257/E21.211; 257/E31.079

(57) ABSTRACT

A method for manufacturing an image sensor includes forming an isolation area in a semiconductor substrate, forming a plurality of gate insulating layers and a plurality of gates over a transistor area of the semiconductor substrate, forming a photodiode over the semiconductor substrate between the gates and the isolation area, forming a nitride layer over the semiconductor substrate such that tensile stress is applied to the transistor area of the semiconductor substrate, forming a floating diffusion layer over the semiconductor substrate between the gates, and removing the nitride layer over the photodiode, and forming an oxide layer over the photodiode.

The present application claims priority under 35 U.S.C. 119 to Korean Patent Application No. 10-2008-0058124 (filed on Jun. 20, 2008), which is hereby incorporated by reference in its entirety.

### BACKGROUND

In general, an image sensor is a semiconductor device for converting optical images into electric signals, and may be classified as a charge coupled device (CCD) or a complementary metal oxide silicon (CMOS) image sensor.

The CMOS image sensor employs a switching mode to sequentially detect an output of each unit pixel using MOS transistors. The MOS transistors are formed over a semiconductor substrate corresponding to the unit pixels through a CMOS technology using peripheral devices, such as a controller and a signal processor.

The semiconductor chip area of a CMOS image sensor is mainly divided into photodiode area and transistor area. The photodiode area converts light into electrons, and the transistor area constitutes a circuit to drive the CMOS image sensor.

The photodiode area is a core area in the CMOS image sensor. The photodiode area is generally formed as an N-type area implanted with arsenic (As) ions to convert light incident from the outside into electrical signals. Electrons generated from a photodiode are transferred into a floating diffusion layer through a transfer transistor charged by electric signals. At this time, if the speed and number of electrons passing through the transfer transistor are insufficient, the operation of the image sensor may be degraded.

For example, since a gate electrode has capacitance by self-resistance, the operating speed of a transistor may be degraded by the resistance and the capacitance thereof, and power consumption may be increased. In other words, since the self-resistance and the capacitance of the transfer transistor exert a negative influence on the speed and number of electrons which are generated from the photodiode and pass through the channel formed by a gate of the transfer transistor, the self-resistance and the capacitance become restrictive factors limiting the operating characteristics of the image sensor.

### SUMMARY

Embodiments relate to an image sensor and a method for manufacturing the same, capable of improving the operation reliability for the image sensor by increasing the mobility of electrons generated from a photodiode when the electrons are transferred to a floating diffusion layer through a transfer transistor.

According to embodiments, an image sensor may include a semiconductor substrate having an isolation area and a transistor area. A plurality of gates may be formed over the transistor area of the semiconductor substrate. A photodiode may be formed over the semiconductor substrate between the gates and the isolation area. A floating diffusion layer may be formed between the gates, and a nitride layer may be formed over the transistor area of the semiconductor substrate including the gates and the floating diffusion layer to apply tensile stress to the transistor area.

According to embodiments, a method for manufacturing an image sensor may include forming an isolation area in a semiconductor substrate, forming a plurality of gate insulating layers over a transistor area of the semiconductor substrate, forming a plurality of gates over the gate insulating layers, forming a photodiode over the semiconductor substrate between the gates and the isolation area, forming a nitride layer over the semiconductor substrate such that tensile stress is applied to the transistor area of the semiconductor substrate, forming a floating diffusion layer over the semiconductor substrate between the gates, removing the nitride layer over the photodiode, and forming an oxide layer over the photodiode.

### DRAWINGS

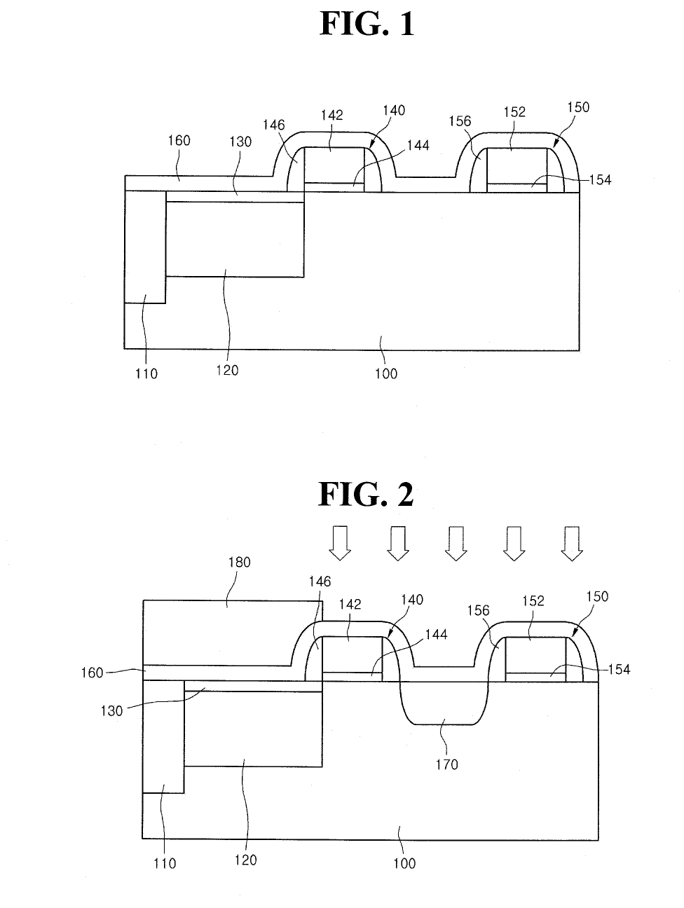

Example FIG. 1 is a side sectional view showing the structure of an image sensor according to embodiments after a photodiode and a transistor have been formed.

Example FIG. 2 is a side sectional view showing the structure of the image sensor according to embodiments after a floating diffusion layer has been formed.

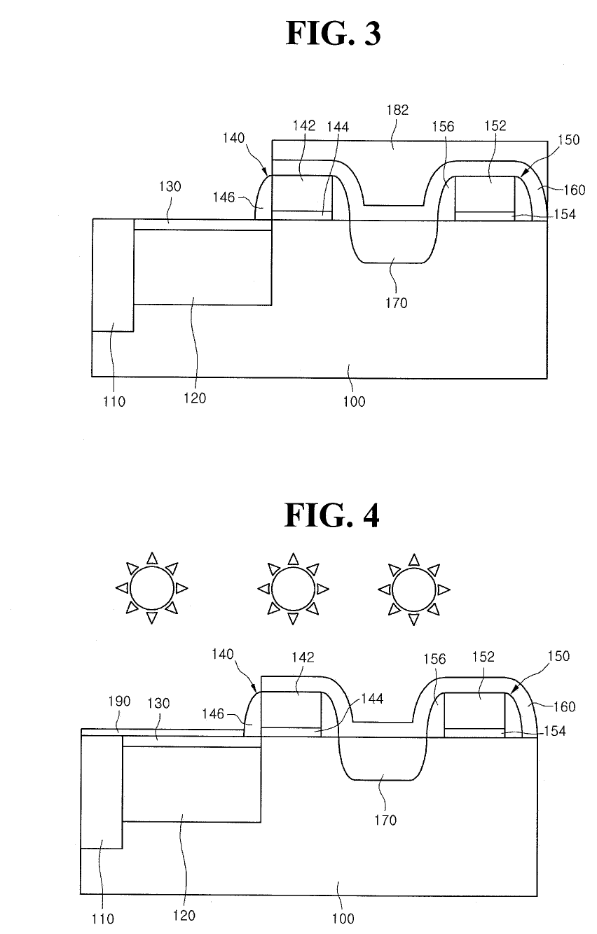

Example FIG. 3 is a side sectional view showing the structure of the image sensor according to embodiments after a nitride layer has been removed from the photodiode.

Example FIG. 4 is a side sectional view showing the structure of the image sensor according to embodiments after an oxide layer has been formed over the photodiode.

### DESCRIPTION

Hereinafter, an image sensor and a method for manufacturing the same according to embodiments will be described in detail with reference to accompanying drawings. Example FIG. 1 is a sectional view showing the structure of an image sensor according to embodiments after a photodiode 120 and transistors 140 and 150 have been formed.

A transistor area includes a plurality of transistors. The transistor area may include a transfer transistor Tx that transfers electric signals generated from the photodiode 120, an FD layer that stores the electric signals transferred from the transfer transistor Tx, a reset transistor Rx that supplies power to the FD layer, an access transistor Ax that applies the electric signals and gate potential thereof is changed as the electric signals are stored in the FD layer, and a select transistor that outputs the electric signals applied by the access transistor Ax.

The photodiode 120, and the transfer transistor 140 and the reset transistor 150 are shown in example FIG. 1. When the transistor area is described below, the two transistors 140 and 150 will be representatively described. The select transistor Sx, the access transistor Ax, the transfer transistor Tx, and the reset transistor Rx may have substantially identical components.

After forming a trench in a semiconductor substrate 100, an oxide material is filled in the trench, thereby forming a plurality of isolation areas 110. After sequentially stacking an insulating layer and a polysilicon layer over the semiconductor substrate 100 including the isolation areas 110, a photoresist pattern may be formed to define areas for the transfer transistor 140 and the reset transistor 150.

The insulating layer and the polysilicon layer may be etched using the photoresist pattern as an etch mask, thereby forming a first gate insulating layer 144 and a first gate 142 constituting the transfer transistor 140, and a second gate insulating layer 154 and a second gate 152 constituting the reset transistor 150.

Subsequently, after forming a photoresist pattern over the transistor area including the first gate 142, the substrate may be lightly doped with N-type conductive impurities, thereby forming the photodiode 120. After the photodiode 120 has been formed, the substrate may be doped with P-type conductive impurities to form an ion implantation layer 130, and the photoresist pattern is removed.

After forming spacers 146 and 156 at both sidewalls of the first gate 142 and the second gate 152, a nitride layer 160 may be formed over the entire surface of the semiconductor substrate 100 including the isolation areas 110, the photodiode 120, the first gate 142, and the second gate 152.

The nitride layer 160 may be stacked to exert tensile stress over an FD layer 170 (see example FIG. 2), which is formed through the subsequent process, and the transistor area, especially, a transfer transistor area. For example, the nitride layer 160 may be stacked at a thickness of about 200 Å to about 500 Å through a low pressure chemical vapor deposition (LPCVD) technology.

Example FIG. 2 is a side sectional view showing the structure of the image sensor according to embodiments after the FD layer 170 has been formed. After forming a photoresist pattern 180 having an opening between the first gate 142 and the second gate 152, an ion implantation process may be performed using P-type impurity ions (P+ ions), thereby forming the FD layer 170.

The FD layer 170 may be formed by implanting ions in the range of about 1×10¹⁵ ions/cm² to about 5×10¹⁵ ions/cm² with an ion implantation energy of about 10 keV to about 20 keV. After the FD layer 170 has been formed, the photoresist pattern 180 is removed.

Example FIG. 3 is a side sectional view showing the structure of the image sensor according to embodiments after the nitride layer 160 has been removed from the photodiode 120. After forming a photoresist pattern 182 to open an area of the photodiode 120, an etch process may be performed to remove the nitride layer 160 over the photodiode 120. The removal of the nitride layer 160 over the photodiode 120 is necessary to minimize the loss of light incident onto the photodiode 120.

Example FIG. 4 is a side sectional view showing the structure of the image sensor according to embodiments after an oxide layer 190 has been formed over the photodiode 120. After removing the photoresist pattern 182, a heat treatment process may be performed with respect to the semiconductor substrate 100, thereby forming the oxide layer 190 at an upper portion of the photodiode 120. The heat treatment process may employ a rapid thermal oxidation (RTO) technology, and the oxide layer 190 may have a thickness of about 20 Å to about 40 Å. The oxide layer 190 removes lattice defects occurring in the upper portion of the photodiode 120.

Next, after removing a portion of the nitride 160 over the FD layer 170, the first gate 142, or the second gate 152, an interlayer dielectric layer including a contact plug may be formed, in which the contact plug is electrically connected with the FD layer 170, the first gate 142, or the second gate 152 through the removed portion. The interlayer dielectric layer may be formed in a plurality of layers. The interlayer dielectric layer may include metal interconnections connected with the contact plug.

After sequentially forming a color filter layer and a protective layer over the interlayer dielectric layer, a micro-lens is formed over the protective layer perpendicular to the photodiode 120, thereby completing the image sensor according to embodiments.

According to the image sensor of embodiments, the mobility of electrons generated from the photodiode can be increased when the electrons are transferred to the FD layer 170 through the transfer transistor Tx. Therefore, the operating voltage of the image sensor can be reduced, and the image sensor can be reliably operated.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming an isolation area in a semiconductor substrate;
forming a plurality of gate insulating layers over a transistor area of the semiconductor substrate;
forming a plurality of gates over the gate insulating layers;
forming a photodiode over the semiconductor substrate between the gates and the isolation area;
forming a nitride layer over the semiconductor substrate such that tensile stress is applied to the transistor area of the semiconductor substrate;
forming a floating diffusion layer over the semiconductor substrate between the gates;
removing the nitride layer over the photodiode; and
forming an oxide layer over the photodiode.

2. The method of claim 1, wherein forming the photodiode includes forming an ion implantation layer at an upper portion of the photodiode.

3. The method of claim 1, wherein forming a plurality of gates includes forming spacers over both sidewalls of each gate after the photodiode has been formed.

4. The method of claim 1, wherein the nitride layer is deposited with a thickness of 200 Å to 500 Å.

5. The method of claim 1, wherein forming the floating diffusion layer includes:
forming a photoresist pattern over the photodiode;
forming the floating diffusion layer by implanting impurity ions using the photoresist pattern as an ion implantation mask; and
removing the photoresist pattern.

6. The method of claim 1, wherein forming the oxide layer includes:
forming a photoresist pattern over the semiconductor substrate to open the photodiode;
removing the nitride layer over the photodiode using the photoresist pattern as an etch mask;
removing the photoresist pattern; and
forming the oxide layer over the photodiode.

7. The method of claim 1, wherein the oxide layer is formed at a thickness of about 20 Å to about 40 Å through a heat treatment process.

8. The method of claim 1, including, after forming the oxide layer, forming an interlayer dielectric layer including metal interconnections.

9. The method of claim 8, including:
forming a color filter layer over the interlayer dielectric layer;
forming a protective layer over the color filter layer; and
forming a micro-lens over the color filter layer.

10. An apparatus comprising:
a semiconductor substrate having an isolation area and a transistor area;
a plurality of gates formed over the transistor area of the semiconductor substrate;
a photodiode formed over the semiconductor substrate between the gates and the isolation area;
a floating diffusion layer formed between the gates; and
a nitride layer formed over the transistor area of the semiconductor substrate including the gates and the floating diffusion layer to apply tensile stress to the transistor area.

11. The apparatus of claim 10, further including an oxide layer formed over the photodiode.

12. The apparatus of claim 10, further including an ion implantation layer formed at an upper portion of the photodiode.

13. The apparatus of claim 10, further including spacers formed over both sidewalls of each gate.

14. The apparatus of claim 10, wherein the nitride layer has a thickness of 200 Å to 500 Å.

15. The apparatus of claim 10, wherein the oxide layer has a thickness of 20 Å to 40 Å.

16. The apparatus of claim 10, wherein the transistor area includes at least a transfer transistor for transferring electric signals from the photodiode, a reset transistor, a select transistor, and an access transistor.

17. The apparatus of claim 10, including an interlayer dielectric layer including a contact plug connected to the floating diffusion layer, and metal interconnections connected to the contact plug.

18. The apparatus of claim 17, including:
a color filter layer over the interlayer dielectric layer;
a protective layer over the color filter layer; and
a micro-lens over the color filter layer.

19. An apparatus configured to:
form an isolation area in a semiconductor substrate;
form a plurality of gate insulating layers over a transistor area of the semiconductor substrate;
form a plurality of gates over the gate insulating layers;
form a photodiode over the semiconductor substrate between the gates and the isolation area;
form a nitride layer over the semiconductor substrate such that tensile stress is applied to the transistor area of the semiconductor substrate;
form a floating diffusion layer over the semiconductor substrate between the gates;
remove the nitride layer over the photodiode; and
form an oxide layer over the photodiode.

20. The apparatus claim 19, configured to form the photodiode by forming an ion implantation layer at an upper portion of the photodiode.
